(19) United States
(12) Patent Application Publication
(10) Pub. No.: US 2019/0127631 A1
(43) Pub. Date: May 2, 2019

(54) DISPLAY PANEL AND ENCAPSULATING METHOD THEREOF

(71) Applicants: BOE TECHNOLOGY GROUP CO., LTD., Beijing (CN); HEFEI BOE OPTOELECTRONICS TECHNOLOGY CO., LTD., Hefei (CN)

(72) Inventor: Dongling SUN, Beijing (CN)

(21) Appl. No.: 15/977,365

(22) Filed: May 11, 2018

(30) Foreign Application Priority Data
Oct. 26, 2017 (CN) 201711012994.9

(51) Int. Cl. C09K 11/02; H01L 51/52; G02F 1/1339; B32B 7/12; C09J 7/30; C09J 9/00; C09K 11/69; C09K 11/77; C09K 11/74; G01N 21/64

(52) U.S. Cl. CPC C09K 11/025; H01L 51/5246; G02F 1/1339; B32B 7/12; C09J 7/30; C09J 9/00; C08K 3/22; C09K 11/77; C09K 11/74; G01N 21/643; G02F 2202/28; C09J 2203/326; C09J 2205/102; C09K 11/69

(57) ABSTRACT

The present disclosure provides a display panel and an encapsulating method thereof, the display panel includes: a first substrate; a second substrate; and an adhesive layer disposed between the first substrate and the second substrate; the adhesive layer is located in a peripheral region of the first substrate and the second substrate for sealing the first substrate and the second substrate, wherein the adhesive layer is uniformly mixed with light emitting materials, so that light intensity of the light emitting materials at different positions in the adhesive layer is detected by a detecting device.

### CROSS-REFERENCE TO RELATED APPLICATION

This application claims the priority of China Patent Application No. 201711012994.9, filed in China on Oct. 26, 2017, the entire contents of which are hereby incorporated by reference.

### Technical Field

The present disclosure relates to the field of display technologies, and in particular, to a display panel and an encapsulating method for the display panel.

### Background

Currently, the mainstream display panels include: an OLED (Organic Light-Emitting Diode) display panel and an LCD (Liquid Crystal Display) display panel. The OLED display panel and the LCD display panel require to avoid moisture and oxygen from entering the display panel. In particular, OLED display panel is extremely sensitive to moisture and oxygen. The moisture and oxygen penetrating into the interior of the OLED display panel are the main factors influencing the service life of the OLED display panel. Therefore, high requirement is imposed on an encapsulating process of the display panel.

The current frit encapsulation technology is favored by manufacturers due to advantages such as excellent performance to isolate water and oxygen and simple in process. However, after frit is sintered by using a laser, defects occurred in the display panel, such as fracture, voids or uneven thickness in frit, are difficult to be detected.

### SUMMARY

The present disclosure addresses above defects in the prior art, and provides a display panel and an encapsulating method thereof to at least partially solve the problem that the defective encapsulating of the display panel is difficult to be detected.

In order to achieve above object, the present disclosure provides a display panel, including: a first substrate; a second substrate; and an adhesive layer disposed between the first substrate and the second substrate; the adhesive layer is located in a peripheral region of the first substrate and the second substrate for sealing the first substrate and the second substrate, wherein the adhesive layer is uniformly mixed with light emitting materials, so that light intensity of the light emitting materials at different positions in the adhesive layer is detected by a detecting device.

Optionally, the light emitting material is a photoluminescent material.

Optionally, the photoluminescent material is selected from a group consisting of: an infrared photoluminescent material, an ultraviolet photoluminescent material, and a visible light photoluminescent material

Optionally, a material of the adhesive layer is frit.

Optionally, a wavelength of an excitation peak of the photoluminescent material is 250-400 nm.

Optionally, a wavelength of an emission peak of the photoluminescent material is 900-1100 nm.

The present disclosure further provides an encapsulating method for a display panel, including:

uniformly mixing an adhesive layer material with a light emitting material;

forming the adhesive layer material mixed with the light emitting material in a peripheral region of a first substrate or the second substrate;

aligning the second substrate with the first substrate, and sealing the first substrate and the second substrate by the adhesive layer material mixed with the light emitting material, so as to form an adhesive layer; and

using a detecting device to detect light intensity at different positions of the adhesive layer.

Optionally, the adhesive layer material is frit, and the light emitting material is a photoluminescent material;

a step of sealing the first substrate and the second substrate by the adhesive layer material mixed with the light emitting material further includes:

melting the frit by a laser to bond the first substrate and the second substrate, and exciting the photoluminescent material by the laser so that the photoluminescent material emits light.

Optionally, after detecting the light intensity at different positions of the adhesive layer by using the detecting device, the method further includes:

comparing the light intensity at different positions of the adhesive layer, if the light intensity at at least one of the positions is different from the light intensity at other positions, melting the frit at the position where the light intensity is different from those at other positions by the laser to adjust the light intensity of the light emitting material at the position.

Optionally, the photoluminescent material is selected from a group consisting of: an infrared photoluminescent material, an ultraviolet photoluminescent material, and a visible light photoluminescent material.

### BRIEF DESCRIPTION OF THE DRAWINGS

FIG. 1 is a schematic structural diagram of a display panel provided in an embodiment;

FIG. 2 is a flowchart of a method for manufacturing a display panel provided in an embodiment.

### DETAILED DESCRIPTION OF THE EMBODIMENTS

To enable those skilled in the art to better understand the technical solutions of the present disclosure, a display panel and an encapsulating method thereof provided in the present disclosure will be described in detail below with reference to the accompanying drawings.

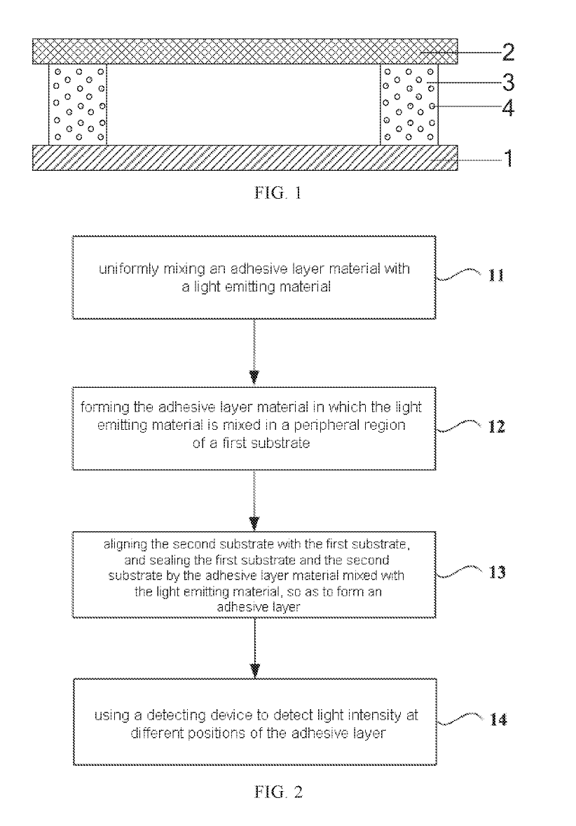

An embodiment of the present disclosure provides a display panel. As shown in FIG. 1, the display panel includes a first substrate 1 and a second substrate 2. An adhesive layer 3 is disposed between the first substrate 1 and the second substrate 2. The adhesive layer 3 is located in peripheral region of the first substrate 1 and the second substrate 2 for sealing the first substrate 1 and the second substrate 2. The adhesive layer 3 is uniformly mixed with light emitting materials 4. The light emitting materials 4 can emit light so that light intensity of the light emitting material 4 at different positions in the adhesive layer 3 can be detected by a detecting device.

Specifically, the light intensity at different positions of the adhesive layer 3 is proportional to the number of the light emitting materials 4. That is, the number of the light emitting materials 4 at positions where the light intensity of the adhesive layer 3 is weak is small, and the number of the light emitting materials 4 at positions where the light intensity of the adhesive layer 3 is strong is large. The number of the light emitting materials 4 is proportional to the thickness of the adhesive layer 3. That is, the thickness of the adhesive layer 3 at positions where the number of the light emitting materials 4 is large is thick, and the thickness of the adhesive layer 3 at positions where the number of the light emitting materials 4 is small is thin. Therefore, the difference in the light intensity of the light emitting materials 4 at different positions in the adhesive layer 3 is detected by the detecting device, and the difference between the light intensity at different positions is compared, so as to determine the difference in the thickness of the adhesive layer 3 at different positions.

In the display panel provided in the embodiment of the present disclosure, the light emitting materials 4 are uniformly mixed within the adhesive layer 3. After the display panel is encapsulated, the light intensity of the light emitting materials 4 in different positions in the adhesive layer 3 can be detected by a detecting device. The thickness of the adhesive layer 3 in the region where the light intensity is relatively large is thick, and the thickness of the region where the light intensity is small is thin. As a result, the difference in thickness at different positions of the adhesive layer 3 can be determined. Consequently, it can be judged whether there is a defect such as fracture, voids, or uneven thicknesses in the adhesive layer 3. A defective encapsulation of the display panel can be detected, and the quality of the display panel can be improved accordingly. Further, the specific position of the defective encapsulation can be also determined so as to analyze factors result in the defective encapsulation.

Optionally, the light emitting material 4 is a photoluminescent material. The photoluminescent material refers to a material capable of emitting light of a certain wavelength under an excitation of light with a certain wavelength. The photoluminescent material may include a light emitting material doped with different rare earth ions. The above-mentioned photoluminescent material has a high light intensity and emits light for a long time, which is facilitate to detect the light intensity at different positions in the adhesive layer 3 by the detecting device.

According to the wavelength of the light emitted from the photoluminescent material after excitation, the photoluminescent material may be selected from a group consisting of: an infrared photoluminescent material, an ultraviolet photoluminescent material, and a visible light photoluminescent material. When the photoluminescent material is an infrared photoluminescent material, the detecting device can detect the light intensity of the infrared light emitted from different positions in the adhesive layer 3. When the photoluminescent material is an ultraviolet photoluminescent material, the detecting device can detect the light intensity of the ultraviolet light emitted from different positions in the adhesive layer 3. When the photoluminescent material is a visible light photoluminescent material, the detecting device can detect the light intensity of visible light emitted from different positions in the adhesive layer 3.

The display panel can be encapsulated by UV glue (UV-curing glue) or frit. Compared with the UV glue encapsulation, the Frit encapsulation is simple and has a strong ability of isolation to moisture and oxygen is strong. Therefore, in illustration of the embodiment of the present disclosure, the display panel is encapsulated by the Frit encapsulation as an example, and correspondingly, the material of the adhesive layer 3 is frit correspondingly.

It should be noted that it is also feasible to encapsulate the display panel by the UV glue. When the display panel is encapsulated by the UV glue, the material of the adhesive layer 3 is an ultraviolet curing adhesive.

When the display panel is encapsulated with frit, the laser melts the frit to adhesively seal the first substrate 1 and the second substrate 2. Optionally, the wavelength of the excitation peak of the photoluminescent material is 250-400 nm. In this way, the wavelength of the excitation light of the photoluminescent material is matched with the wavelength of the laser. That is, the photoluminescent material can be excited by the laser during a process that laser melts the fit, so that the photoluminescent material emits light. As a result, no additional excitation of the photoluminescent material is required, thereby simplifying the encapsulation process.

Optionally, the wavelength of the emission peak of the photoluminescent material is 900-1100 nm. That is, the photoluminescent material is an infrared photoluminescent material. The photoluminescence material emits infrared light after being excited. The detecting device has high detection accuracy with respect to the infrared light, which can detect the light intensity at different positions in the adhesive layer 3 accurately. Specifically, the infrared photoluminescent material may include a GdVO₄ material co-doped with Bi³⁺ and Yb³⁺.

An embodiment of the present disclosure further provides an encapsulating method for a display panel. As shown in FIG. 1 and. FIG. 2, the method includes:

In step 11: uniformly mixing the adhesive layer material with the light emitting material 4.

Specifically, the light emitting material 4 can be uniformly dispersed in the adhesive layer material by a physical method such as mechanical stirring or ultrasonic dispersion.

It should be noted that, in the embodiment of the present disclosure, it is taken as an example for illustration that the display panel is encapsulated by the Frit encapsulation, and the adhesive layer material is frit correspondingly.

When the adhesive layer material is frit, the step of uniformly mixing the adhesive layer material with the light emitting material 4 specifically includes:

Making the light emitting material 4 into a powder by a solid phase method, and uniformly mixing the powdered light emitting material 4 and the adhesive layer material with each other. Through the above steps, the adhesive layer material and the light emitting material 4 can be mixed uniformly.

Optionally, the light emitting material 4 is a photoluminescent material, and the photoluminescent material has a high light intensity and emits light for a long time.

In step 12: forming the adhesive layer material mixed with the light emitting material 4 in the peripheral region of the first substrate 1 or the second substrate 2.

Specifically, the adhesive layer material mixed with the light emitting material 4 may be coated in the peripheral region of the first substrate 1 or the second substrate 2 by a coating process. Alternatively, and the adhesive layer material mixed with the light emitting material 4 may also be printed in the peripheral region of the first substrate 1 or the second substrate 2 by a screen printing process.

In step 13: aligning the second substrate 2 with the first substrate 1, and sealing the first substrate 1 and the second substrate 2 by the adhesive layer material mixed with the light emitting material 4, so as to form an adhesive layer 3.

Specifically, after the first substrate 1 and the second substrate 2 are bonded and sealed by the adhesive layer material mixed with the light emitting material 4, the adhesive layer 3 is formed.

When the adhesive layer material is frit, the step of sealing the first substrate 1 and the second substrate 2 by the adhesive layer material mixed with the light emitting material 4 specifically includes:

melting the frit by a laser to bond the first substrate 1 and the second substrate 2, and exciting the photoluminescent material by the laser so that the photoluminescent material emits light.

Specifically, the laser may heat the frit to melt the frit, and the frit in the molten state may bond the first substrate 1 and the second substrate 2; after the frit solidifies, the adhesive layer 3 is formed. The above laser also can excite the photoluminescent material so that the photoluminescent material emits light. Therefore, there is no need to provide an additional excitation for the photoluminescent material, and the encapsulating process is simplified accordingly.

It should be noted that the melting point of the light emitting material is greater than the melting point of the fit. During melting of the fit by the laser, the light emitting material does not melt. Therefore, it does not affect the bonding effect of the frit in the molten state on the first substrate 1 and the second substrate 2.

In step 14: detecting the light intensity of the adhesive layer 3 at different positions by using the detecting device.

Specifically, the light intensity of the adhesive layer 3 at different positions is proportional to the number of the light emitting materials 4. That is, the number of the light emitting materials 4 where the light emitting intensity of the adhesive layer 3 is weak is small, and the number of the light emitting materials 4 at positions where the light intensity of the adhesive layer 3 is strong is large. The number of the light emitting materials 4 is proportional to the thickness of the adhesive layer 3. That is, the thickness of the adhesive layer 3 at positions where the number of the light emitting materials 4 is large is thick, and the thickness of the adhesive layer 3 at positions where the number of the light emitting materials 4 is small is thin. Therefore, the difference in the thickness of the adhesive layer 3 at different positions can be determined by detecting the difference in the light intensity of the light emitting materials 4 at different positions in the adhesive layer 3.

An embodiment of the present disclosure provides an encapsulating method for a display panel. Firstly, uniformly mixing the adhesive layer material with the light emitting material 4; then, forming the adhesive layer material mixed with the light emitting material 4 in the peripheral region of the first substrate 1 or the second substrate 2; aligning the second substrate 2 with the first substrate 1, and sealing the first substrate 1 and the second substrate 2 by the adhesive layer material mixed with the light emitting material 4, so as to form an adhesive layer 3; finally, detecting the light intensity at different positions of the adhesive layer 3 by using a detecting device. Accordingly, the difference in the thickness of the adhesive layer 3 at different positions can be used to judge whether there is any defects such as fracture, voids or uneven thickness in the adhesive layer 3. A defective encapsulation of the display panel can be detected, and the quality of the display panel can be improved accordingly. Further, the specific position of the defective encapsulation can be also determined so as to analyze factors result in this defective encapsulation.

Further, after detecting the light intensity at different positions of the adhesive layer 3 by using a detecting device, the method further includes:

In step 15: comparing the light intensity of the adhesive layer 3 at different positions. If the light intensity at at least one of the positions is different from the light intensity at other positions, melting the frit at the position where the light intensity is different from other positions by the laser, so as to adjust the light intensity of the light emitting material 4 at the position.

Specifically, the detecting device detects the light intensity of the adhesive layer 3 at different positions, and then compares the difference in light intensity of the adhesive layer 3 at different positions. If the light intensity at at least one of the positions is greatly different from those at other positions, it indicates that defects such as fracture, voids, or uneven thickness exist at such position where the light intensity is greatly different from those at other positions. The frit at the position where the light intensity differs greatly from others is melted by a laser. Since the molten frit has fluidity, the defects such as fracture, voids, or thickness unevenness in the frit can be repaired, so that the difference in light intensity of the adhesive layer 3 at different positions is reduced. Through the above method, the defective encapsulating of the display panel can be repaired, so that the yield rate of the display panel can be improved.

It should be noted that, “the light intensity at at least one of the positions is different from other positions” is refer to that the light intensity at at least one of the positions is greatly different from those at other positions. If the difference of the light intensity is greater than a preset threshold, the difference is large. If the difference of the light intensity is less than or equal to the preset threshold, the difference is small. The preset threshold needs to be determined based on a deviation of the thickness of the adhesive layer 3 in operation of an actual process.

It should also be noted that the photoluminescent material may be selected from a group consisting of: an infrared photoluminescent material, an ultraviolet photoluminescent material, and a visible light photoluminescent material. Specifically, the infrared photoluminescent material may emit infrared light after being excited, and the ultraviolet photoluminescent material may emit ultraviolet light after being excited, and the visible light photoluminescent material may emit visible light after being excited. Optionally, the photoluminescent material is an infrared photoluminescent material, and the detecting device has high detection accuracy of the infrared light, and can detect the light intensity at different positions in the adhesive layer 3 more accurately.

It can be understood that the above embodiments are merely exemplary embodiments employed for illustrating the principle of the present disclosure, but the present disclosure is not limited thereto. For a person of ordinary skilled in the art, various variations and improvements may be made without departing from the spirit and essence of the present disclosure, and these variations and improvements are also considered to be within the protection scope of the present disclosure.

1. A display panel, including:
a first substrate;
a second substrate; and
an adhesive layer disposed between the first substrate and the second substrate; the adhesive layer is located in a peripheral region of the first substrate and the second substrate for sealing the first substrate and the second substrate,
wherein the adhesive layer is uniformly mixed with light emitting materials, so that light intensity of the light emitting materials at different positions in the adhesive layer is detected by a detecting device.

2. The display panel according to claim 1, wherein the light emitting material is a photoluminescent material.

3. The display panel according to claim 2, wherein the photoluminescent material is selected from a group consisting of: an infrared photoluminescent material, an ultraviolet photoluminescent material, and a visible light photoluminescent material

4. The display panel according to claim 3, wherein a material of the adhesive layer is frit.

5. The display panel according to claim 4, wherein a wavelength of an excitation peak of the photoluminescent material is 250-400 nm.

6. The display panel according to claim 3, wherein a wavelength of an emission peak of the photoluminescent material is 900-1100 nm.

7. An encapsulating method for a display panel, including:
uniformly mixing an adhesive layer material with a light emitting material;
forming the adhesive layer material mixed with the light emitting material in a peripheral region of a first substrate or the second substrate;
aligning the second substrate with the first substrate, and sealing the first substrate and the second substrate by the adhesive layer material mixed with the light emitting material, so as to form an adhesive layer; and
using a detecting device to detect light intensity at different positions of the adhesive layer.

8. An encapsulating method according to claim 7, wherein the adhesive layer material is frit, and the light emitting material is a photoluminescent material;
a step of sealing the first substrate and the second substrate by the adhesive layer material mixed with the light emitting material further includes:
melting the frit by a laser to bond the first substrate and the second. substrate, and exciting the photoluminescent material by the laser so that the photoluminescent material emits light.

9. An encapsulating method according to claim 8, wherein after detecting the light intensity at different positions of the adhesive layer by using the detecting device, the method further includes:
comparing the light intensity at different positions of the adhesive layer, if the light intensity at at least one of the positions is different from the light intensity at other positions, melting the frit at the position where the light intensity is different from those at other positions by the laser to adjust the light intensity of the light emitting material at the position.

10. An encapsulating method according to claim 8, wherein the photoluminescent material is selected from a group consisting of: an infrared photoluminescent material, an ultraviolet photoluminescent material, and a visible light photoluminescent material.
